(19) United States
(12) Patent Application Publication
(10) Pub. No.: US 2025/0357222 A1
(43) Pub. Date: Nov. 20, 2025

(54) TEST DEVICE, WAFER AND TEST METHOD

(71) Applicant: YANGTZE MEMORY TECHNOLOGIES CO., LTD., Wuhan (CN)

(72) Inventors: Man HU, Wuhan (CN); Jing WEI, Wuhan (CN); Ke LIANG, Wuhan (CN); Chenhui LI, Wuhan (CN); Lei JIN, Wuhan (CN); HongTao LIU, Wuhan (CN); XiangNan ZHAO, Wuhan (CN)

(21) Appl. No.: 18/810,103

(22) Filed: Aug. 20, 2024

(30) Foreign Application Priority Data
May 16, 2024 (CN) 2024106130498

(51) Int. Cl. H01L 21/66; G01R 31/28

(52) U.S. Cl. CPC H01L 22/32; G01R 31/2884; G01R 31/2831

(57) ABSTRACT

Examples of the present disclosure provide a test device, a wafer, and a test method. The test device includes a control circuit connected to M groups of pads and N groups of test units, wherein M and N are both integers greater than 1; a number of test units included in each group of test units is less than or equal to M, and a total number of the test units is greater than M. The control circuit is configured to receive a test signal, select one of the N groups of test units based on the test signal, and connect at least some of the M groups of pads to the test units in the selected group of test units in one-to-one correspondence.

### CROSS-REFERENCE TO RELATED APPLICATIONS

The present application claims priority to Chinese Patent Application No. 2024106130498, which was filed May 16, 2024, is titled “TEST DEVICE, WAFER AND TEST METHOD,” and is hereby incorporated herein by reference in its entirety.

### TECHNICAL FIELD

The present disclosure relates to the field of semiconductor technology, and more particularly to a test device, a wafer, and a test method.

### BACKGROUND

In the semiconductor manufacturing process, it is usually needed to manufacture a wafer acceptance test (WAT) structure on a scribe line between semiconductor devices on a wafer, so that wafer acceptance testing can be performed after manufacturing of the integrated circuit is completed and before the wafer leaves the factory.

### SUMMARY

In view of this, the main purpose of the present disclosure is to provide a test device, a wafer, and a test method.

In order to achieve the above purpose, the technical solution of the present disclosure is implemented as follows:

According to a first aspect of examples of the present disclosure, there is provided a test device, comprising: a control circuit, M groups of pads and N groups of test units, wherein M and N are both integers greater than 1, a number of test units comprised in each group of test units is less than or equal to M, and a total number of the test units is greater than M; and a control circuit configured to receive a test signal, select one of the N groups of test units based on the test signal, and connect at least some of the M groups of pads to the test units in a selected group of test units in one-to-one correspondence.

In the above solution, at least one group of pads is connected with multiple test units in different groups of test units.

In the above solution, a same one of the test units is connected with at most one group of pads.

In the above solution, the control circuit comprises a first control sub-circuit and a second control sub-circuit, and the second control sub-circuit is connected with the first control sub-circuit, the M groups of pads and the N groups of test units; the first control sub-circuit is configured to generate a selection signal based on the test signal, and the selection signal is configured to indicate to select one of the N groups of test units; and the second control sub-circuit is configured to: receive the selection signal, and enable a connection between the test units in the selected group of test units and at least some of the groups of pads according to the selection signal.

In the above solution, the first control sub-circuit at least comprises a decoder, wherein the decoder has N output terminals, and is configured to receive the test signal and output an N-bit selection signal to the second control sub-circuit through the N output terminals.

In the above solution, the first control sub-circuit comprises one decoder and N comparators; an output terminal of the decoder is connected with input terminals of the N comparators, and output terminals of the N comparators are in one-to-one correspondence with the N groups of test units; the decoder is configured to receive the test signal and output a decoded signal to the input terminals of the N comparators; each of the N comparators is configured to receive a reference signal and the decoded signal and output a 1-bit selection sub-signal, and N 1-bit selection sub-signals output by the N comparators constitute an N-bit selection signal; and each group of test units corresponds to a unique reference signal.

In the above solution, the second control sub-circuit comprises N groups of transistors that are connected with the N groups of test units in one-to-one correspondence; a first controlled terminal of a transistor in each group of transistors is connected with one group of pads, a second controlled terminal of the transistor is connected with the test unit correspondingly connected with the group of pads, and a control terminal of the transistor is configured to receive one bit of the N-bit selection signal.

In the above solution, a number of terminals to be led out from each of the test units is one or more; and a number of pads comprised in each group of pads is the same as a number of the terminals to be led out from each of the test units.

In the above solution, the test units comprise word lines or bit lines.

In the above solution, the N is equal to 2, the M is equal to 4, and a number of the word lines comprised in each group of test units is equal to 4; a second control sub-circuit of the control circuit comprises 2 groups of transistors, the 2 groups of transistors are in one-to-one correspondence with 2 groups of test units, and a number of the transistors comprised in each group of transistors is equal to 4; and each group of pads is connected with 2 test units in different groups of test units.

In the above solution, a plurality of word lines or bit lines comprised in each group of test units are spaced apart.

In the above solution, at least two of the plurality of word lines or bit lines comprised in each group of test units are adjacent.

According to a second aspect of examples of the present disclosure, there is provided a wafer comprising: a plurality of semiconductor devices; scribe lines each located between the semiconductor devices to separate the semiconductor devices; and the test devices of any of the examples of the first aspect located in the scribe lines.

According to a third aspect of examples of the present disclosure, there is provided a test method, comprising: receiving a test signal; and selecting one of N groups of test units based on the test signal, and connecting at least some of M groups of pads to the test units in a selected group of test units in one-to-one correspondence, wherein M and N are both integers greater than 1, a number of the test units comprised in each group of test units is less than or equal to M, and a total number of the test units is greater than M.

In the above solution, the test method further comprises: testing the test units in the selected group of test units via at least some of the groups of test pads by using a test probe.

In the above solution, the test method comprises: generating a selection signal based on the test signal, wherein the selection signal is configured to indicate to select one of the N groups of test units; and receiving the selection signal, and enabling a connection between the test units in the selected group of test units and at least some of the groups of pads according to the selection signal.

According to the test device provided by the examples of the present disclosure, a plurality of test units are reasonably grouped, and at least some of the limited number of groups of pads are reused by the control circuit, such that when one group of test units is selected for testing, at least some of the groups of pads are connected with the test units in the selected group of test units in one-to-one correspondence. Therefore, the requirement of separately obtaining the electrical performance of each test unit through the group of pads can be satisfied, which is conducive to providing numerical reference for the design of semiconductor devices and increasing the yield of semiconductor devices. Meanwhile, there is no need to additionally increase the number of groups of pads, which is conducive to increasing the area utilization rate of the wafer.

### BRIEF DESCRIPTION OF THE DRAWINGS

FIG. 1 is a block diagram I of a test device according to an example of the present disclosure;

FIG. 2 is a block diagram II of a test device according to an example of the present disclosure;

FIG. 3 is a block diagram III of a test device according to an example of the present disclosure;

FIG. 4 is a block diagram IV of a test device according to an example of the present disclosure;

FIG. 5 is a block diagram V of a test device according to an example of the present disclosure;

FIG. 6 is a block diagram VI of a test device according to an example of the present disclosure;

FIG. 7 is a schematic diagram I of a circuit structure of a test device according to an example of the present disclosure;

FIG. 8 is a schematic diagram II of a circuit structure of a test device according to an example of the present disclosure;

FIG. 9 is a schematic diagram of a circuit structure of a first control sub-circuit according to an example of the present disclosure;

FIG. 10 is a schematic diagram of a method of dividing a group of test units according to an example of the present disclosure;

FIG. 11 is a schematic diagram of a wafer provided by examples of the present disclosure; and

FIG. 12 is an implementation flow diagram of a test method provided by examples of the present disclosure.

### DETAILED DESCRIPTION

The technical solutions of the present disclosure will be further described below in detail in conjunction with the drawings and examples. Although the example implementation methods of the present disclosure are shown in the drawings, it is to be understood that the present disclosure may be implemented in various forms and should not be limited by the implementations set forth herein. Rather, these implementations are provided for a more thorough understanding of the present disclosure, and can fully convey the scope of the present disclosure to those skilled in the art.

In the following, the present disclosure is described in more details with reference to the drawings by means of examples. The advantages and features of the present disclosure will be clearer from the following description. It should be noted that the drawings are all in a very simplified form and use imprecise scales, only for the purpose of a convenient and clear description of the examples of the present disclosure.

It should be understood that, spatially relative terms, such as “beneath”, “below”, “lower”, “under”, “over”, “upper”, and the like, may be used herein for ease of description to describe the relationship between one element or feature and other elements or features as illustrated in the drawings. It is to be understood that, the spatially relative terms are intended to further encompass different orientations of a device in use or operation in addition to the orientation depicted in the drawings. For example, if a device in the drawings is turned over, then the elements or the features described as being “below” or “under” or “beneath” other elements will be oriented as being “on” the other elements or features. Therefore, the example terms “below” and “beneath” may comprise both upper and lower orientations. The device may be orientated otherwise (rotated by 90 degrees or other orientations), and the spatially descriptive terms used herein are interpreted accordingly.

The terms used herein are only intended to describe the specific examples, and are not used as limitations of the present disclosure. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

In order to understand the characteristics and the technical contents of the examples of the present disclosure in more detail, implementation of the examples of the present disclosure is set forth in detail below in conjunction with the drawings, and the appended drawings are only used for reference and illustration, instead of being used to limit the examples of the present disclosure.

It is to be noted that the technical solutions set forth in the examples of the present disclosure may be combined freely without conflict.

With the continuous development of the semiconductor device, the process flow comprises many complex process steps, and each step may have a specific process manufacturing deviation, which finally results in a reduction in the yield. In order to increase the yield of semiconductor device, it is a common practice to acquire data necessary for improving the manufacturing process and design yield through a wafer acceptance test.

However, with higher complexity of the semiconductor device, the number of test units in a scribe line corresponding to the semiconductor device also increases. Considering the large area of pads, the number of pads disposed in the scribe line is often less than the number of the test units, such that it is difficult to effectively monitor the processes and the test units based on the number of pads in the scribe line. Thus, the problems arising from the processes and the test units cannot be quickly discovered and solved, thereby affecting the yield of semiconductor device.

Furthermore, with the improvement of semiconductor manufacturing technology, the size of semiconductor devices decreases, which not only increases the number of the semiconductor devices formed on a single wafer, but also reduces the area of scribe lines. As a result, the number of processes and test units that need to be monitored also increases. How to quickly discover and solve the problems that arise from the processes and the test units and reduce the impact on the yield of semiconductor devices has become an urgent problem to be solved.

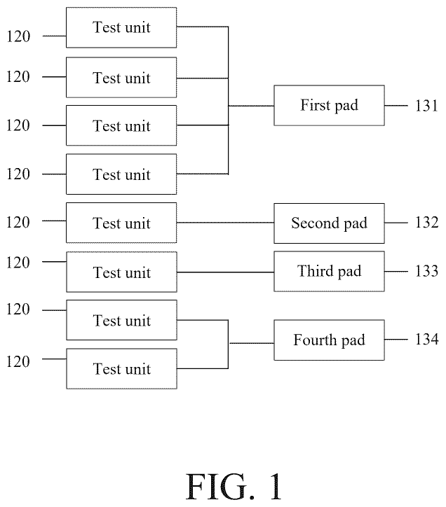

In an example, there is at least a case that the same pad is simultaneously connected with a plurality of test units in a scribe line. As shown in FIG. 1, 4 pads are connected with 8 test units, a first pad 131 is connected with 4 test units 120, a second pad 132 is connected with I test unit 120, a third pad 133 is connected with 1 test unit 120, and a fourth pad 134 is connected with 2 test units 120, thereby failing to meet the requirement of separately acquiring the electrical performance of each of the 8 test units shown in FIG. 1 through the pad, for example, failing to separately acquire the electrical performance of each of the 4 test units 120 connected with the first pad 131, which is not conducive to providing a numerical reference for the design of semiconductor device; while increasing the number of pads will increase the footprint of the scribe line, which is not conducive to increasing the area utilization rate of the wafer.

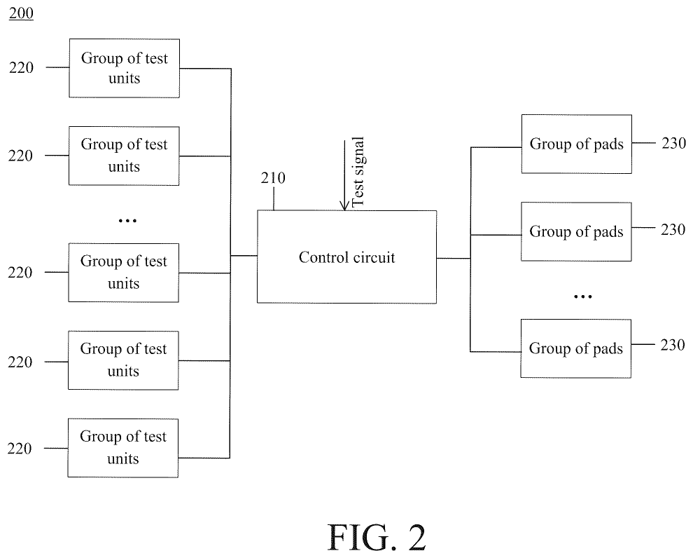

On that basis, examples of the present disclosure provide a test device. As shown in FIG. 2, the test device 200 comprises a control circuit 210, M groups of pads 230 and N groups of test units 220, M and N are both integers greater than 1, the number of test units comprised in each group of test units 220 is less than or equal to M, and the total number of the test units is greater than M; and the control circuit 210 is configured to: receive a test signal, select one of the N groups of test units 220 based on the test signal, and connect at least some of the M groups of pads 230 to the test units in the selected group of test units in one-to-one correspondence.

It is to be noted that the number of the test units comprised in each group of test units may be the same or different. On the premise that the number of the test units comprised in each group of test units is less than or equal to the number of groups of pads, the number of the test units comprised in each group of test units may be set according to actual demands.

In some examples, at least one group of pads is connected with multiple test units in different groups of test units.

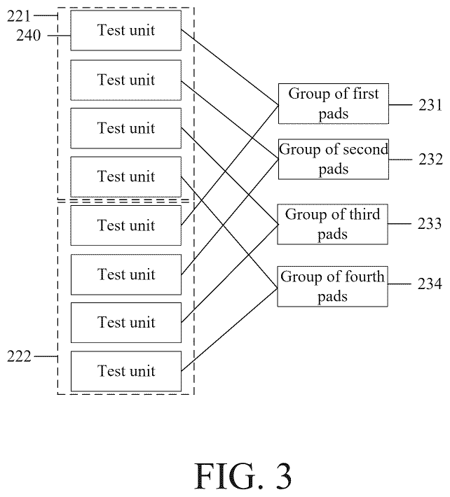

In some examples, as shown in FIG. 3, the test device comprises 4 groups of pads (a first group of pads 231, a second group of pads 232, a third group of pads 233 and a fourth group of pads 234) and 2 groups of test units (a first group of test units 221 and a second group of test units 222). The first group of test units 221 and the second group of test units 222 each comprise 4 test units 240. Each group of pads is connected with 2 test units in different groups of test units. In an example, the first group of pads 231 is connected with I test unit in the first group of test units 221 and 1 test unit in the second group of test units 222.

In some examples, when the first group of test units 221 is the selected group of test units, the second group of test units 222 is an unselected group of test units, and the first group of pads 231, the second group of pads 232, the third group of pads 233 and the fourth group of pads 234 are connected with the test units 240 in the selected first group of test units 221 in one-to-one correspondence.

When the second group of test units 222 is the selected group of test units, the first group of test units 221 is the unselected group of test units, and the first group of pads 231, the second group of pads 232, the third group of pads 233 and the fourth group of pads 234 are connected with the test units 240 in the selected second group of test units 222 in one-to-one correspondence.

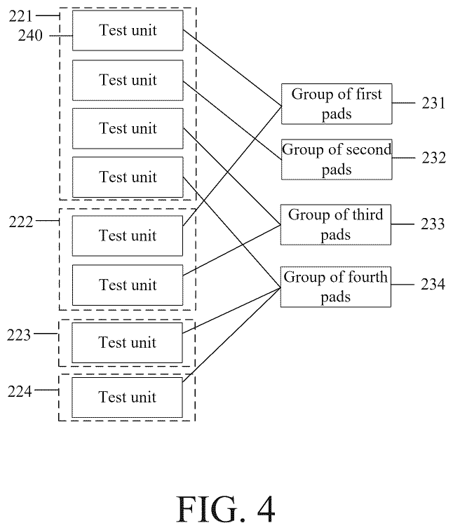

In other examples, as shown in FIG. 4, the test device comprises 4 groups of pads (a first group of pads 231, a second group of pads 232, a third group of pads 233 and a fourth group of pads 234) and 4 groups of test units (a first group of test units 221, a second group of test units 222, a third group of test units 223 and a fourth group of test units 224). The first group of test units 221 comprises 4 test units 240, the second group of test units 222 comprises 2 test units 240, and the third group of test units 223 and the fourth group of test units 224 each comprise 1 test unit 240. Some of the groups of pads are connected with multiple test units in different groups of test units, while some of the groups of pads are only connected with I test unit in one group of test units. In an example, the first group of pads 231 is connected with I test unit in the first group of test units 221 and 1 test unit in the second group of test units 222. The second group of pads 232 is only connected with 1 test unit in the first group of test units 221. The third group of pads 233 is connected with 1 test unit in the first group of test units 221 and I test unit in the second group of test units 222. The fourth group of pads 234 is connected with I test unit in the first group of test units 221, 1 test unit in the third group of test units 223 and I test unit in the fourth group of test units 224.

In some examples, when the first group of test units 221 is the selected group of test units, the first group of pads 231, the second group of pads 232, the third group of pads 233 and the fourth group of pads 234 are connected with 4 test units 240 in the first group of test units 221 in one-to-one correspondence.

When the second group of test units 222 is the selected group of test units, the first group of pads 231 and the third group of pads 233 are connected with 2 test units 240 in the second group of test units 222 in one-to-one correspondence.

When the third group of test units 223 is the selected group of test units, the fourth group of pads 234 is correspondingly connected with I test unit 240 in the third group of test units 223.

When the fourth group of test units 224 is the selected group of test units, the fourth group of pads 234 is correspondingly connected with 1 test unit 240 in the fourth group of test units 224.

As such, by grouping the plurality of test units reasonably and reusing at least some of the limited number of groups of pads through the control circuit, when one group of test units is selected for testing, at least some of the groups of pads are connected with the test units in the selected group of test units in one-to-one correspondence. Therefore, the requirement of separately acquiring the electrical performance of each test unit through the group of pads can be satisfied, which is contributive to providing a numerical reference for the design of semiconductor device and increasing the yield of semiconductor device. At the same time, there is no need to additionally increase the number of groups of pads, which is conducive to increasing the area utilization rate of the wafer.

It is to be noted that, for case of illustration of a relationship of correspondence between the group of test units and the group of pads, FIGS. 3 and 4 are brief schematic diagrams after omitting the control circuit between the group of test units and the group of pads in FIG. 2, and a specific connection relationship of the control circuit with the group of test units and the group of pads will be further described later.

In some examples, the same group of pads is connected with at most 1 test unit in the same group of test units. In an example, as shown in FIGS. 3 and 4, any group of pads will not be connected with multiple test units in the same group of test units simultaneously. As such, when one group of test units is selected, the same group of pads will not be connected with multiple test units simultaneously.

In some examples, the same test unit is connected with at most one group of pads. The electrical performance of one test unit can be acquired via one group of pads, thereby avoiding a connection of the same test unit with a plurality of groups of pads, which may efficiently improve the utilization rate of the groups of pads.

In some examples, the number of terminals to be led out from each test unit is one or more; and the number of pads comprised in each group of pads is the same as the number of the terminals to be led out from each test unit. In other words, the electrical performance of one test unit can be acquired via one group of pads.

In some examples, the test unit is a four-terminal device, such as a field-effect transistor. The four terminals are source, drain, gate and base respectively, and the number of pads comprised in each group of pads is 4.

In some examples, the test unit is a two-terminal device, such as a resistor and/or a capacitor, and the number of pads comprised in each group of pads is 2.

In some examples, the test units comprise word lines or bit lines, and the number of pads comprised in each group of pads is 1.

It is to be noted that the above-mentioned type and number of test units are only an example, the examples of the present disclosure are not limited thereto, and the type and number of test units and the number of pads comprised in each group of pads can be reasonably set according to the requirements.

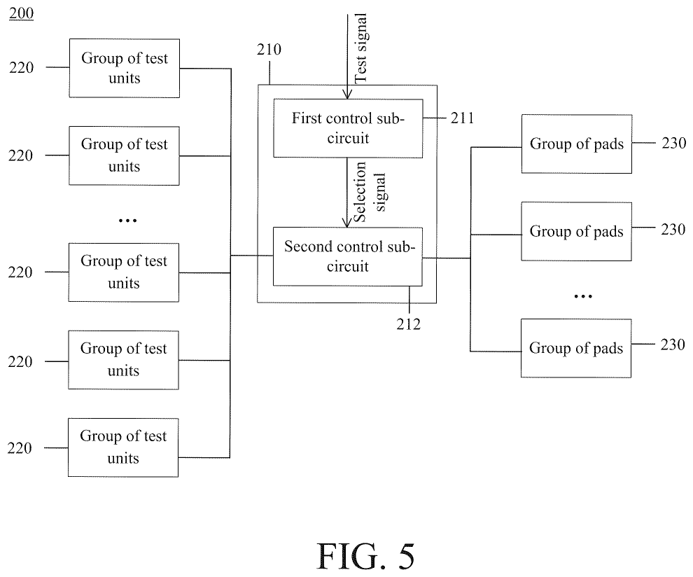

In some examples, as shown in FIG. 5, the control circuit 210 comprises a first control sub-circuit 211 and a second control sub-circuit 212, and the second control sub-circuit 212 is connected with the first control sub-circuit 211, M groups of pads 230 and N groups of test units 220; the first control sub-circuit 211 is configured to generate a selection signal based on a test signal, and the selection signal is configured to indicate to select one of the N groups of test units 220; and the second control sub-circuit 212 is configured to: receive the selection signal, and enable a connection between test units in the selected group of test units 220 and at least some of the groups of pads 230 according to the selection signal.

In some examples, the first control sub-circuit at least comprises a decoder having N output terminals; and the decoder is configured to receive the test signal and output an N-bit selection signal to the second control sub-circuit through the N output terminals.

In some examples, an even number of phase inverters may be connected to the output terminals of the decoder to increase the driving capability of the circuit.

In some implementations, the decoder has P input terminals and N output terminals, P and N are both integers greater than 1, and N=2^{P}. In an example, the decoder of the first control sub-circuit is configured to receive a P-bit test signal and output an N-bit selection signal to the second control sub-circuit through the N output terminals. For the test signal received each time, only one of the N output terminals of the decoder is at an active level, while the remaining output terminals are at an opposite level. An output signal may be active at a high level or active at a low level.

It is to be noted that the selection of the decoder is related to the number of groups of test units, and the number of the output terminals of the decoder is equal to the number of groups of test units.

In an example, the decoder includes, but is not limited to, a 2-4 decoder, a 3-8 decoder and a 4-16 decoder.

In an example, the test device comprising 4 groups of test units as shown in FIG. 4 is illustrated as an example. The decoder may be a 2-4 decoder, i.e., the decoder has 2 input terminals (A and B) and 4 output terminals (Y0, Y1, Y2, and Y3). Table 1 is a truth table for the 2-4 decoder. As can be seen from Table 1, when a 2-bit test signal received by the decoder is 00, an output 4-bit selection signal is 0111; when the 2-bit test signal received by the decoder is 10, the output 4-bit selection signal is 1011; when the 2-bit test signal received by the decoder is 01, the output 4-bit selection signal is 1101; and when the 2-bit test signal received by the decoder is 11, the output 4-bit selection signal is 1110.

It is to be noted that, in this example, the low level is set to be active. Typically, the 2-4 decoder further has an enable terminal, and when the enable terminal is active (typically active at a low level), the decoder can work normally. If the enable terminal is inactive, all the output terminals output high levels, which means that all the 4 output terminals of the decoder output inactive levels.

TABLE 1

| | |
|---|---|
| Input | Output |

| A | B | Y3 | Y2 | Y1 | Y0 |
|---|---|---|---|---|---|
| 0 | 0 | 0 | 1 | 1 | 1 |
| 1 | 0 | 1 | 0 | 1 | 1 |
| 0 | 1 | 1 | 1 | 0 | 1 |
| 1 | 1 | 1 | 1 | 1 | 0 |

In some examples, the relationship of correspondence between the test signal and the group of test units may be preset. In an example, when the test signal is 00, it means that the first group of test units is selected; and when the test signal is 10, it means that the second group of test units is selected. When the test signal is 01, it means that the third group of test units is selected. When the test signal is 11, it means that the fourth group of test units is selected.

It is to be noted that Table 1 is only an example illustration of a truth table for a decoder, and different decoders may have different enable terminals and output active levels, such that it is necessary to refer to the truth table for a specific decoder during use.

In some examples, the second control sub-circuit comprises N groups of transistors, and the N groups of transistors are connected with the N groups of test units in one-to-one correspondence; a first controlled terminal of a transistor in each group of transistors is connected with one group of pads, a second controlled terminal of the transistor is connected with the test unit correspondingly connected with the group of pads, and a control terminal of the transistor is configured to receive one bit of the N-bit selection signal.

It is to be noted that the number of the transistors comprised in each group of transistors may be the same or different, and the number the transistors comprised in each group of transistors may be set according to the number of test units comprised in the group of test units corresponding to the group of transistors.

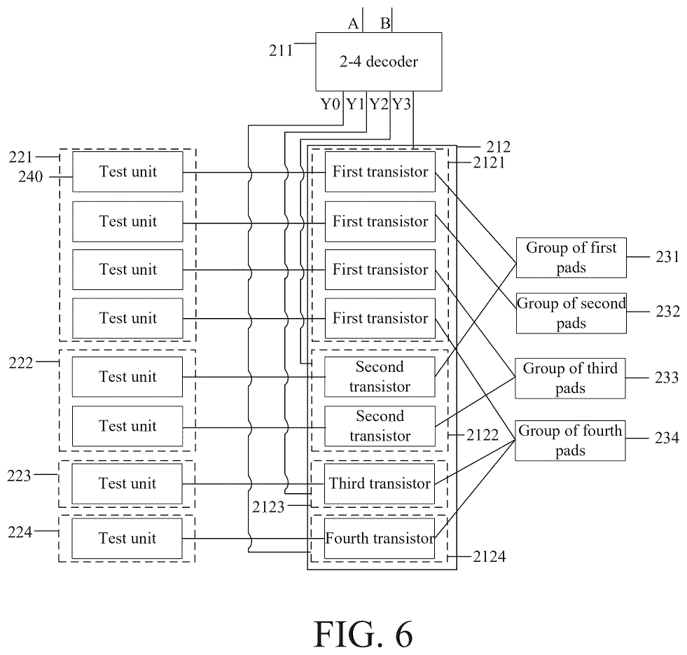

In some implementations, as an example for illustration, N is equal to 4 and the test units comprise word lines or bit lines. As shown in FIG. 6, the first control sub-circuit 211 comprises a 2-4 decoder, and the decoder has 2 input ports A and B and 4 output ports (a first output port Y0, a second output port Y1, a third output port Y2 and a fourth output port Y3); and the second control sub-circuit 212 comprises 4 groups of transistors (a first group of transistors 2121, a second group of transistors 2122, a third group of transistors 2123 and a fourth group of transistors 2124), and the 4 groups of transistors are connected with 4 groups of test units in one-to-one correspondence. In an example, the first group of transistors 2121 is correspondingly connected with the first group of test units 221, the second group of transistors 2122 is correspondingly connected with the second group of test units 222, the third group of transistors 2123 is correspondingly connected with the third group of test units 223, and the fourth group of transistors 2124 is correspondingly connected with the fourth group of test units 224.

The first group of transistors 2121 comprises 4 first transistors, the second group of transistors 2122 comprises 2 second transistors, the third group of transistors 2123 comprises 1 third transistor, and the fourth group of transistors 2124 comprises 1 fourth transistor.

In some implementations, the first controlled terminal of the transistor in each group of transistors is connected with one group of pads, the second controlled terminal of the transistor is connected with the test unit correspondingly connected with the group of pads, and the control terminal of the transistor is configured to receive one bit of the N-bit selection signal.

In an example, as shown in FIG. 6, a first controlled terminal of the first transistor in the first group of transistors 2121 is connected with the first group of pads 231, a second controlled terminal of the first transistor in the first group of transistors 2121 is connected with the test unit 240 in the first group of test units 221 correspondingly connected with the first group of pads 231, and a control terminal of the first transistor in the first group of transistors 2121 is configured to receive one bit of a 4-bit selection signal output by the fourth output port Y3 of the 2-4 decoder.

In an example, as shown in FIG. 6, a first controlled terminal of the second transistor in the second group of transistors 2122 is connected with the second group of pads 232, a second controlled terminal of the second transistor in the second group of transistors 2122 is connected with the test unit 240 in the second group of test units 222 correspondingly connected with the second group of pads 232, and a control terminal of the second transistor in the second group of transistors 2122 is configured to receive one bit of a 4-bit selection signal output by the third output port Y2 of the 2-4 decoder.

In an example, as shown in FIG. 6, a first controlled terminal of the third transistor in the third group of transistors 2123 is connected with the third group of pads 233, a second controlled terminal of the third transistor in the third group of transistors 2123 is connected with the test unit 240 in the third group of test units 223 correspondingly connected with the third group of pads 233, and a control terminal of the third transistor in the third group of transistors 2123 is configured to receive one bit of a 4-bit selection signal output by the second output port Y1 of the 2-4 decoder.

In an example, as shown in FIG. 6, a first controlled terminal of the fourth transistor in the fourth group of transistors 2124 is connected with the fourth group of pads 234, a second controlled terminal of the fourth transistor in the fourth group of transistors 2124 is connected with the test unit 240 in the fourth group of test units 224 correspondingly connected with the fourth group of pads 234, and a control terminal of the fourth transistor in the fourth group of transistors 2124 is configured to receive one bit of a 4-bit selection signal output by the first output port Y0 of the 2-4 decoder.

It is to be noted that the types of the first transistor, the second transistor, the third transistor and the fourth transistor are the same, for example, the first transistor, the second transistor, the third transistor and the fourth transistor are all PMOS transistors, or the first transistor, the second transistor, the third transistor and the fourth transistor are all NMOS transistors.

The control terminals of the transistors in the same group of transistors all receive one bit of the N-bit selection signal output from the same output port of the decoder, and only one bit of the N-bit selection signal output by the decoder is at an active level, and the other (N−1) bits are at an inactive level. Therefore, when one of the plurality of groups of test units is selected, the transistor in one group of transistors correspondingly connected with the selected group of test units will enable a connection between the group of test units and the group of pads in response to one bit of the N-bit selection signal output by the decoder being at an active level.

It is to be noted that, due to a preset relationship of one-to-one correspondence between the test signal and the group of test units, the selection signal generated by the test signal via the decoder also has a relationship of one-to-one correspondence with the group of test units, and each group of transistors can enable a connection between the corresponding group of test units and group of pads according to the selection signal.

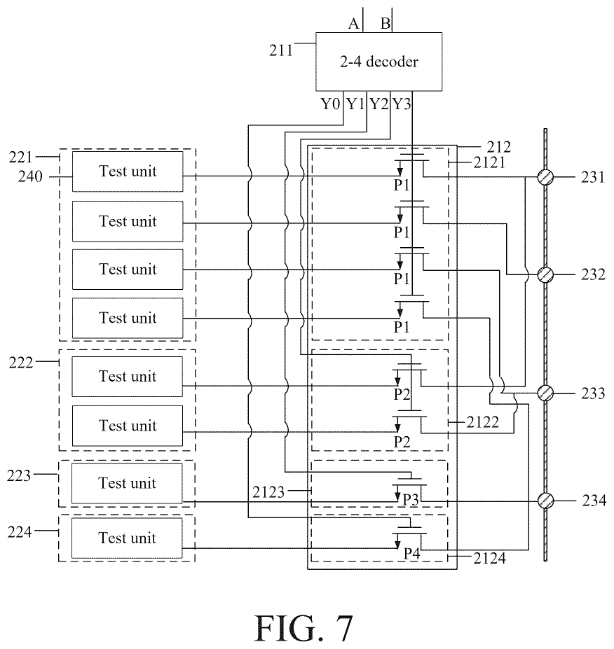

FIG. 7 is a schematic diagram of a circuit structure of the test device when the first transistor, the second transistor, the third transistor and the fourth transistor shown in FIG. 6 are all PMOS transistors. The test units comprise word lines or bit lines, and the number of pads comprised in each group of pads is 1.

As can be seen from the truth table for the 2-4 decoder shown in Table 1, when a 2-bit test signal received by the decoder is 00, an output 4-bit selection signal is 0111, each first transistor P1 in the first group of transistors enables a connection between the test unit 240 in the first group of test units 221 and the group of pads in response to an active level “0” output by the fourth output port Y3. The second transistor P2 disconnects the test unit 240 in the second group of test units 222 from the group of pads in response to an inactive level “1” output by the third output port Y2, and the case of the third transistor P3 and the fourth transistor P4 is similar to that of the second transistor P2, which is no longer repeated here.

When other groups of test units are selected, a turn-on or turn-off process of each group of transistors may be understood by referring to the above process of selecting the first group of test units.

In some examples, N is equal to 2, M is equal to 4, and the number of the word lines comprised in each group of test units is equal to 4. The second control sub-circuit of the control circuit comprises 2 groups of transistors that are in one-to-one correspondence with the 2 groups of test units, and the number of the transistors comprised in each group of transistors is equal to 4. Each group of pads is connected with 2 test units in different groups of test units.

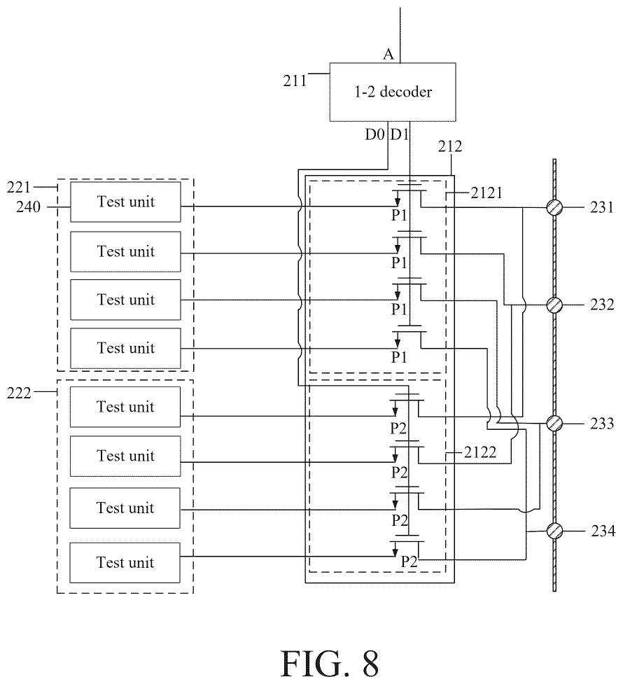

As shown in FIG. 8, the relationship of correspondence between 2 groups of test units and 4 groups of pads in FIG. 8 is the same as that in FIG. 3. The first control sub-circuit 211 in FIG. 8 comprises a 1-2 decoder that has 1 input port A and 2 output ports (a first output port D0 and a second output port D1). Table 2 is a truth table for the 1-2 decoder. As can be seen from Table 2, when a 1-bit test signal received by the decoder is 0, an output 2-bit selection signal is 01, and when a 2-bit test signal received by the decoder is 1, an output 2-bit selection signal is 10.

TABLE 2

| | |
|---|---|
| Input | Output |

| A | D1 | D0 |
|---|---|---|
| 0 | 0 | 1 |
| 1 | 1 | 0 |

The number of the word lines comprised in each group of test units shown in FIG. 8 is equal to 4. The second control sub-circuit of the control circuit comprises a first group of transistors 2121 and a second group of transistors 2122, the first group of transistors 2121 comprises 4 first transistors P1, and the second group of transistors 2122 comprises 4 first transistors P2. The first group of transistors 2121 corresponds to the first group of test units 221, and the second group of transistors 2122 corresponds to the second group of test units 222. The first group of pads 231, the second group of pads 232, the third group of pads 233 and the fourth group of pads 234 each comprise 1 pad.

As can be seen from FIG. 8 and Table 2, when a 1-bit test signal received by the decoder is 0, an output 2-bit selection signal is 01, each first transistor P1 in the first group of transistors enables a connection between the test unit 240 in the first group of test units 221 and the group of pads in response to an active level “0” output by the second output port D1. The second transistor P2 disconnects the test unit 240 in the second group of test units 222 from the group of pads in response to an inactive level “1” output by the first output port D0.

In some examples, the first control sub-circuit comprises one decoder and N comparators, an output terminal of the decoder is connected with input terminals of the N comparators, and output terminals of the N comparators are in one-to-one correspondence with the N groups of test units. The decoder is configured to receive a test signal and output a decoded signal to the input terminals of the N comparators. Each comparator is configured to receive a reference signal and the decoded signal and output a 1-bit selection sub-signal, and N 1-bit selection sub-signals output by the N comparators constitute an N-bit selection signal. Each group of test units corresponds to a unique reference signal.

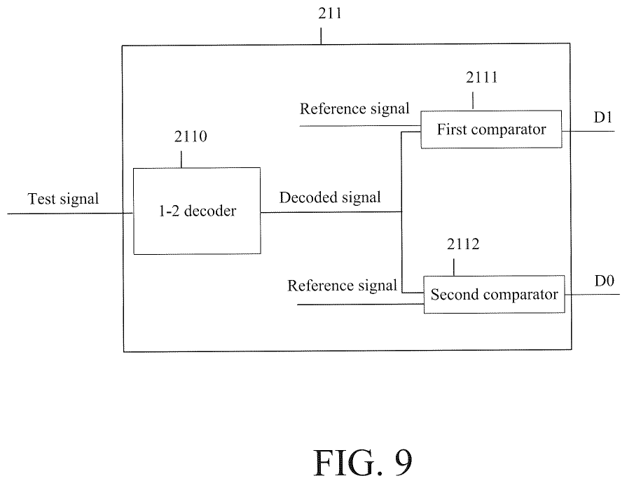

In an example, as an example for illustration, N is equal to 2. As shown in FIG. 9, the first control sub-circuit 211 comprises one 1-2 decoder 2110 and 2 comparators (a first comparator 2111 and a second comparator 2112).

An output terminal of the 1-2 decoder 2110 is connected with input terminals of the 2 comparators, and output terminals of the 2 comparators are in one-to-one correspondence with 2 test units. The 1-2 decoder 2110 is configured to receive the test signal and output the decoded signal to the input terminals of the 2 comparators. Each comparator is configured to receive a reference signal and the decoded signal and output a 1-bit selection sub-signal, and two 1-bit selection sub-signals output by the 2 comparators constitute a 2-bit selection signal. Each group of test units corresponds to a unique reference signal.

Here, an illustration is made in conjunction with the truth table for the 1-2 decoder shown in Table 2 and a connection relationship of the first control sub-circuit with the group of test units, the second control sub-circuit and the group of pads shown in FIG. 8. When a 1-bit test signal received by the 1-2 decoder 2110 shown in FIG. 9 is 0, it means that the first group of test units is selected, and a 2-bit decoded signal output by the 1-2 decoder 2110 is 01. An output terminal of the first comparator 2111 corresponds to the first group of test units shown in FIG. 8, and an output terminal of the second comparator 2112 corresponds to the second group of test units shown in FIG. 8. The first comparator 2111 receives the decoded signal 01 and a reference signal 01 corresponding to the first group of test units, and outputs a comparison result “1” as a 1-bit selection sub-signal. The second comparator 2112 receives the decoded signal 01 and a reference signal 10 corresponding to the second group of test units, and outputs a comparison result “0” as a 1-bit selection sub-signal. As such, the first control sub-circuit outputs a 2-bit selection signal 10.

In FIG. 9, the output terminal of the first comparator 2111 serves as a second output terminal D1 of the first control sub-circuit, and the output terminal of the second comparator 2112 serves as a second output terminal D0 of the first control sub-circuit. The way of connection of the transistors in the first control sub-circuit and the second control sub-circuit in FIG. 9 may be understood by referring to the way of connection of the 1-2 decoder in FIG. 8.

It is to be noted that, when the result as shown in FIG. 9 is used for the first control sub-circuit, the transistors need to be set as NMOS transistors, such that when the first group of test units is selected, the transistor corresponding to the first group of test units is turned on in response to “1” output by the first comparator 2111, and the transistor corresponding to the second group of test units is turned off in response to “0” output by the first comparator 2111.

It is to be noted that the relationship of correspondence between the reference signal and the group of test units may be preset, an Nth comparator is correspondingly connected with an Nth group of test units, and at the same time, one input terminal of the Nth comparator is configured to receive a reference signal corresponding to the Nth group of test units.

It is to be noted that the positions of the test units shown in FIGS. 2 to 8 are only some examples of a method for dividing the groups of test units, and are not used to limit actual positions of the test units in the present disclosure.

In some examples, at least two of the plurality of word lines or at least two of the plurality of bit lines comprised in each group of test units are adjacent.

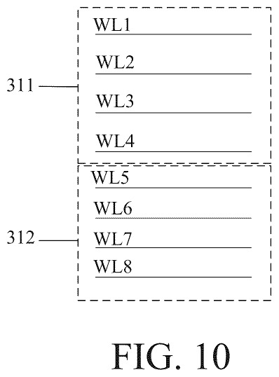

In an example, with reference to FIG. 10, the first group of test units 311 comprises 4 word lines (WL1, WL2, WL3 and WL4), and WL1 and WL2 are adjacent, WL2 and WL3 are adjacent, and WL3 and WL4 are adjacent. The second group of test units 312 comprises 4 word lines (WL5, WL6, WL7 and WL8), and WL5 and WL6 are adjacent, WL6 and WL7 are adjacent, and WL7 and WL8 are adjacent. As the size of the semiconductor device shrinks, the spacing between the adjacent word lines or the adjacent bit lines also decreases. When dividing the groups of test units, at least two of the plurality of word lines or at least two of the plurality of bit lines comprised in each group of test units are adjacent. The electrical performance of the word lines or the bit lines that are adjacent is acquired during the testing, which is contributive to providing a numerical reference for the design of semiconductor device, for example, analyzing the impact of spacing variation on the electrical performance according to the test result.

In some examples, the plurality of word lines or bit lines comprised in each group of test units are spaced apart. In an example, WL1, WL3, WL5 and WL7 shown in FIG. 10 are divided into the first group of test units, and WL2, WL4, WL6 and WL8 shown in FIG. 10 are divided into the second group of test units. As such, connection lines between the group of pads and the test units in the group of test units have similar distances, and interferences, such as resistance, etc., caused by the connection lines during the testing are also similar, thereby facilitating the acquisition of more accurate electrical performance of the test units.

According to the test device provided by the examples of the present disclosure, the plurality of test units are reasonably grouped, and at least some of the limited number of groups of pads are reused by the control circuit, such that when one group of test units is selected for testing, at least some of the groups of pads are connected with the test units in the selected group of test units in one-to-one correspondence. Therefore, the requirement of separately acquiring the electrical performance of each test unit through the group of pads can be satisfied, which is conducive to providing a numerical reference for the design of semiconductor device and increasing the yield of semiconductor device. At the same time, there is no need to additionally increase the number of groups of pads, which is conducive to increasing the area utilization rate of the wafer.

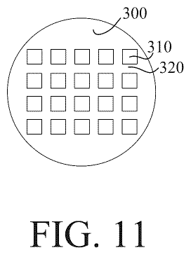

Examples of the present disclosure further provide a wafer. As shown in FIG. 11, the wafer 300 comprises a plurality of semiconductor devices 310; scribe lines 320 each located between the semiconductor devices 310 to separate the semiconductor devices 310; and the test device as described in the aforementioned examples located in the scribe lines 320.

It is to be noted that test units in the test device disposed in the scribe lines 320 correspond separately to a process or a structure of the semiconductor device 310 to be monitored.

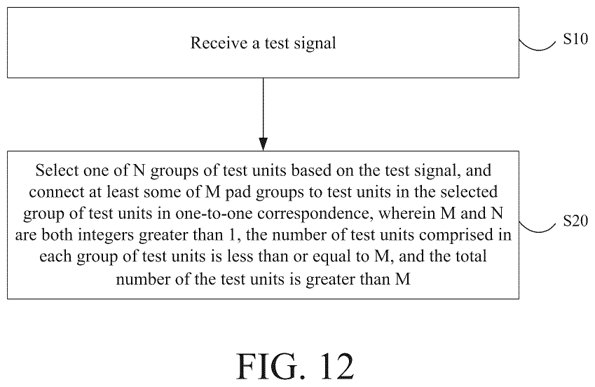

Examples of the present disclosure further provide a test method. FIG. 12 is an implementation flow diagram of a test method provided by examples of the present disclosure. As shown in FIG. 12, the test method comprises:
S10: receiving a test signal; and
S20: selecting one of N groups of test units based on the test signal, and connecting at least some of M groups of pads to test units in the selected group of test units in one-to-one correspondence, M and N are both integers greater than 1, the number of the test units comprised in each group of test units is less than or equal to M, and the total number of the test units is greater than M.

In S20, selecting one of the N groups of test units based on the test signal and connecting at least some of the M groups of pads to the test units in the selected group of test units in one-to-one correspondence comprises: generating a selection signal based on the test signal, wherein the selection signal is configured to indicate to select one of the N groups of test units; and receiving the selection signal, and enabling a connection between the test unit in the selected group of test units and at least some of the groups of pads according to the selection signal.

With reference to FIG. 6 and Table 1, the first control sub-circuit 211 comprises a 2-4 decoder, and the decoder has 2 input ports A and B and 4 output ports (a first output port Y0, a second output port Y1, a third output port Y2 and a fourth output port Y3). The second control sub-circuit 212 comprises 4 groups of transistors (a first group of transistors 2121, a second group of transistors 2122, a third group of transistors 2123 and a fourth group of transistors 2124), and the 4 groups of transistors are connected with the 4 groups of test units in one-to-one correspondence.

In some implementations, the first controlled terminal of the transistor in each group of transistors is connected with one group of pads, the second controlled terminal of the transistor is connected with the test unit correspondingly connected with the group of pads, and the control terminal of the transistor is configured to receive one bit of the N-bit selection signal.

In an example, the test method comprises: generating a 4-bit selection signal 0111 based on a 2-bit test signal 00. The 4-bit selection signal indicates to select one (such as the first group of test units 221) of the 4 groups of test units.

The test method further comprises: receiving the 4-bit selection signal 0111, and enabling a connection between the test unit in the selected group of test units and at least some of the groups of pads according to the 4-bit selection signal 0111. In an example, the first transistor in the first group of transistors 2121 is turned on according to a first bit “0” in the 4-bit selection signal 0111, the second transistor in the second group of transistors 2122 is turned on according to a second bit “1” in the 4-bit selection signal 0111, the third transistor in the third group of transistors 2123 is turned on according to a third bit “1” in the 4-bit selection signal 0111, and the fourth transistor in the fourth group of transistors 2124 is turned on according to a fourth bit “1” in the 4-bit selection signal 0111.

The control terminals of the transistors in the same group of transistors all receive one bit of the N-bit selection signal output from the same output port of the decoder, and only one bit of the N-bit selection signal output by the decoder is at an active level, and the other (N−1) bits are at an inactive level. Therefore, when one of the plurality of groups of test units is selected, the transistor in one group of transistors correspondingly connected with the selected group of test units will enable a connection between the test unit and the group of pads in response to one bit of the N-bit selection signal output by the decoder being at an active level.

It is to be noted that, due to the preset relationship of one-to-one correspondence between the test signal and the group of test units, the selection signal generated by the test signal via the decoder also has a relationship of one-to-one correspondence with the group of test units, and each group of transistors can enable a connection between the corresponding group of test units and group of pads according to the selection signal.

In some examples, the test method further comprises: testing the test units in the selected group of test units via at least some of the groups of test pads by using a test probe. Since the individual electrical performance of each test unit can be acquired by the test method of the examples of the present disclosure, it is more conducive to improving the manufacturing process and design yield of semiconductor device.

It is to be understood that references to “an example” or “some examples” throughout this specification mean that specific features, structures, or characteristics related to the example(s) are comprised in at least one example of the present disclosure. Therefore, “in an example” or “in some examples” presented throughout this specification does not necessarily refer to the same example. In addition, these specific features, structures or characteristics may be incorporated in one or more examples in any proper manner. It is to be understood that, in various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure. The above sequence numbers of the examples of the present disclosure are only for description, and do not represent advantages or disadvantages of the examples.

The above descriptions are merely specific implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A test device, comprising:
a control circuit; and
M groups of pads and N groups of test units connected to the control circuit, wherein M and N are both integers greater than 1, a number of test units in each of the N groups of test units is less than or equal to M, and a total number of the test units among the N groups of test units is greater than M,
wherein the control circuit is configured to receive a test signal, select one of the N groups of test units based on the test signal, and connect at least some of the M groups of pads to the test units in the selected group of test units in one-to-one correspondence.

2. The test device of claim 1, wherein at least one group of pads among the M groups of pads is connected with multiple test units in different groups of test units among the N groups of test units.

3. The test device of claim 2, wherein a same one of the test units among the N groups of test units is connected with at most one group of pads among the M groups of pads.

4. The test device of claim 2, wherein the control circuit comprises a first control sub-circuit and a second control sub-circuit, and the second control sub-circuit is connected with the first control sub-circuit, the M groups of pads and the N groups of test units;
the first control sub-circuit is configured to generate a selection signal based on the test signal, and the selection signal is configured to indicate to select the one of the N groups of test units; and
the second control sub-circuit is configured to: receive the selection signal, and enable a connection between the test units in the selected group of test units and at least some of the M groups of pads according to the selection signal.

5. The test device of claim 4, wherein
the first control sub-circuit at least comprises a decoder, wherein the decoder has N output terminals and is configured to receive the test signal and output an N-bit selection signal to the second control sub-circuit through the N output terminals.

6. The test device of claim 4, wherein the first control sub-circuit comprises one decoder and N comparators; and
an output terminal of the decoder is connected with input terminals of the N comparators, and output terminals of the N comparators are in one-to-one correspondence with the N groups of test units; the decoder is configured to receive the test signal and output a decoded signal to the input terminals of the N comparators; each of the N comparators is configured to receive a reference signal and the decoded signal and output a 1-bit selection sub-signal, and N 1-bit selection sub-signals output by the N comparators constitute an N-bit selection signal; and each group of test units among the N groups of test units corresponds to a unique reference signal.

7. The test device of claim 5, wherein
the second control sub-circuit comprises N groups of transistors, and the N groups of transistors are connected with the N groups of test units in one-to-one correspondence; and
a first controlled terminal of a transistor in each group of transistors among the N groups of transistors is connected with one group of pads among the M groups of pads, a second controlled terminal of the transistor is connected with the test unit correspondingly connected with the group of pads, and a control terminal of the transistor is configured to receive one bit of the N-bit selection signal.

8. The test device of claim 1, wherein a number of terminals to be led out from each of the test units among the N groups of test units is one or more; and a number of pads in each group of pads among the M groups of pads is the same as the number of the terminals to be led out from each of the test units.

9. The test device of claim 1, wherein the test units in the N groups of test units comprise word lines or bit lines.

10. The test device of claim 9, wherein the N is equal to 2, the M is equal to 4, and a number of the word lines in each group of test units among the N groups of test units is equal to 4; and
a second control sub-circuit of the control circuit comprises 2 groups of transistors that are in one-to-one correspondence with 2 groups of test units among the N groups of test units, and a number of transistors in each of the groups of transistors is equal to 4; and each group of pads among the M groups of pads is connected with 2 test units in different groups of test units among the N groups of test units.

11. The test device of claim 9, wherein word lines or bit lines in each group of test units among the N groups of test units are spaced apart.

12. The test device of claim 9, wherein at least two of a plurality of word lines or bit lines in each group of test units among the N groups of test units are adjacent such that no other word lines or bit lines are present therebetween.

13. A wafer, comprising:
a plurality of semiconductor devices;
scribe lines located between the semiconductor devices to separate the semiconductor devices; and
test devices located in the scribe lines, the test devices each comprising:
a control circuit; and
M groups of pads and N groups of test units connected to the control circuit, wherein M and N are both integers greater than 1, a number of test units in each of the N groups of test units is less than or equal to M, and a total number of the test units among the N groups of test units is greater than M,
wherein the control circuit is configured to receive a test signal, select one of the N groups of test units based on the test signal, and connect at least some of the M groups of pads to the test units in a selected group of test units in one-to-one correspondence.

14. The wafer of claim 13, wherein at least one group of pads among the M groups of pads is connected with multiple test units in different groups of test units among the N groups of test units.

15. The wafer of claim 14, wherein a same one of the test units among the N groups of test units is connected with at most one group of pads among the M groups of pads.

16. The wafer of claim 14, wherein the control circuit comprises a first control sub-circuit and a second control sub-circuit, and the second control sub-circuit is connected with the first control sub-circuit, the M groups of pads and the N groups of test units;
the first control sub-circuit is configured to generate a selection signal based on the test signal, and the selection signal is configured to indicate to select the one of the N groups of test units; and
the second control sub-circuit is configured to: receive the selection signal, and enable a connection between the test units in the selected group of test units and at least some of the M groups of pads according to the selection signal.

17. The wafer of claim 16, wherein
the first control sub-circuit at least comprises a decoder, wherein the decoder has N output terminals and is configured to receive the test signal and output an N-bit selection signal to the second control sub-circuit through the N output terminals.

18. A test method, comprising:
receiving a test signal; and
selecting one of N groups of test units based on the test signal; and
connecting at least some of M groups of pads to the test units in the selected group of test units in one-to-one correspondence,
wherein M and N are both integers greater than 1, a number of the test units in each of the N groups of test units is less than or equal to M, and a total number of the test units among the N groups of test units is greater than M.

19. The test method of claim 18, further comprising:
testing the test units in the selected group of test units via at least some of the groups of test pads among the M groups of pads by using a test probe.

20. The test method of claim 18, further comprising:
generating a selection signal based on the test signal, wherein the selection signal is configured to indicate to select one of the N groups of test units; and
receiving the selection signal, and enabling a connection between the test units in the selected group of test units and at least some of the groups of pads among the M groups of pads according to the selection signal.
